(19) United States
(12) Patent Application Publication
(10) Pub. No.: US 2022/0246493 A1
(43) Pub. Date: Aug. 4, 2022

(54) WATER-COOLING DEVICE WITH COMPOSITE HEAT-DISSIPATING STRUCTURE

(71) Applicant: AMULAIRE THERMAL TECHNOLOGY, INC., New Taipei City (TW)

(72) Inventors: CHENG-SHU PENG, New Taipei City (TW); TZE-YANG YEH, New Taipei City (TW); CHIH-HUNG SHIH, Hsinchu County (TW)

(21) Appl. No.: 17/166,075

(22) Filed: Feb. 3, 2021

(51) Int. Cl. H01L 23/473; H01L 23/367

(52) U.S. Cl. CPC H01L 23/473; F28F 1/325; H01L 23/3672

(57) ABSTRACT

A water-cooling device with a composite heat-dissipating structure is provided, which includes a casing, a main heat-dissipating structure and a layered heat-dissipating structure. The casing is used for accommodating a working fluid, and the casing includes a heat-dissipating substrate. The main heat-dissipating structure includes a plurality of heat-dissipating fins arranged vertically and in parallel to each other that are connected to the heat-dissipating substrate. The layered heat-dissipating structure includes a plurality of horizontal heat-dissipating bodies arranged horizontally and in parallel to each other that are connected to the plurality of heat-dissipating fins arranged vertically and in parallel to each other, and a distance between the plurality of horizontal heat-dissipating bodies arranged horizontally and in parallel to each other is greater than or equal to a distance between the plurality of heat-dissipating fins arranged vertically and in parallel to each other.

### FIELD OF THE DISCLOSURE

The present disclosure relates to a water-cooling device and more particularly to a water-cooling device with a composite heat-dissipating structure.

### BACKGROUND OF THE DISCLOSURE

Radiators are widely used in various products. Generally speaking, higher-end products usually use water-cooling radiators, which have the advantages of quietness and a stable cooling performance compared to air-cooling radiators. The water-cooling radiator is usually attached to a heat source to dissipate heat. The heat source first conducts waste heat generated thereby to heat-dissipating fins inside the water-cooling radiator, and then the heat-dissipating fins transfer the waste heat to a coolant, so that the coolant takes the waste heat away. However, as the demand for heat dissipation increases, structural surface areas of the heat dissipation fins formed by metal injection molding (MIM) or forging will reach a processing limit, and a surface area that is in contact with the coolant cannot be further increased, thus failing to meet higher demands for heat dissipation.

### SUMMARY OF THE DISCLOSURE

In response to the above-referenced technical inadequacies, the present disclosure provides a water-cooling device with a composite heat-dissipating structure.

In one aspect, the present disclosure provides a water-cooling device with a composite heat-dissipating structure, which includes a casing, a main heat-dissipating structure and a layered heat-dissipating structure. The casing is used for accommodating a working fluid, and includes a heat-dissipating substrate. The main heat-dissipating structure includes a plurality of heat-dissipating fins arranged vertically and in parallel to each other that are connected to the heat-dissipating substrate. The layered heat-dissipating structure includes a plurality of horizontal heat-dissipating bodies arranged horizontally and in parallel to each other that are connected to the plurality of heat-dissipating fins arranged vertically and in parallel to each other, and a distance between the plurality of horizontal heat-dissipating bodies arranged horizontally and in parallel to each other is greater than or equal to a distance between the plurality of heat-dissipating fins arranged vertically and in parallel to each other.

In certain embodiments, the horizontal heat-dissipating body is a metal plate with a high thermal conductivity.

In certain embodiments, the horizontal heat-dissipating body is a metal mesh with a high thermal conductivity.

In certain embodiments, the plurality of heat-dissipating fins and the heat-dissipating substrate are formed integrally or by soldering.

In certain embodiments, the plurality of heat-dissipating fins and the plurality of horizontal heat-dissipating bodies form an integral composite heat-dissipating structure.

In certain embodiments, a lowermost horizontal heat-dissipating body of the plurality of horizontal heat-dissipating bodies is in contact with or combined to the heat-dissipating substrate.

In certain embodiments, the water-cooling device with a composite heat-dissipating structure further includes a heat-dissipating substructure. The heat-dissipating substructure includes a plurality of substrate grooves formed on the heat-dissipating substrate.

In certain embodiments, the substrate grooves are formed on the heat-dissipating substrate by a nano-scaled pulsed laser processing.

In certain embodiments, the water-cooling device with a composite heat-dissipating structure further includes a heat-dissipating substructure. The heat-dissipating substructure includes a plurality of substrate grooves formed on the heat-dissipating substrate and a plurality of fin grooves formed on the heat-dissipating fins.

In certain embodiments, the substrate grooves are formed on the heat-dissipating substrate by a nano-scaled pulsed laser processing, and the fin grooves are formed on the heat-dissipating fins by a nano-scaled pulsed laser processing.

Therefore, in the water-cooling device with a composite heat dissipation structure provided by the present disclosure, through the plurality of horizontal heat-dissipating bodies arranged horizontally and parallel to each other being connected to the plurality of heat-dissipating fins arranged vertically and in parallel to each other, a surface area of an overall structure that is in contact with the working fluid is increased, so as to achieve an enhanced heat dissipation effect. Moreover, the distance between the horizontal heat-dissipating bodies arranged horizontally and in parallel to each other is greater than or equal to the distance between the heat-dissipating fins arranged vertically and in parallel to each other, which allows the working fluid to pass through more easily, so that a large amount of the working fluid can flow through spaces between the heat-dissipating bodies.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings, in which:

FIG. 1 is a side view of a water-cooling device with a composite heat-dissipating structure according to a first embodiment of the present disclosure;

FIG. 2 is a schematic perspective view showing horizontal heat-dissipating bodies illustrated in FIG. 1 in another configuration;

FIG. 3 is a side view of a water-cooling device with a composite heat-dissipating structure according to a second embodiment of the present disclosure;

FIG. 4 is a side view of a water-cooling device with a composite heat-dissipating structure according to a third embodiment of the present disclosure; and

FIG. 5 is a side view of a water-cooling device with a composite heat-dissipating structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

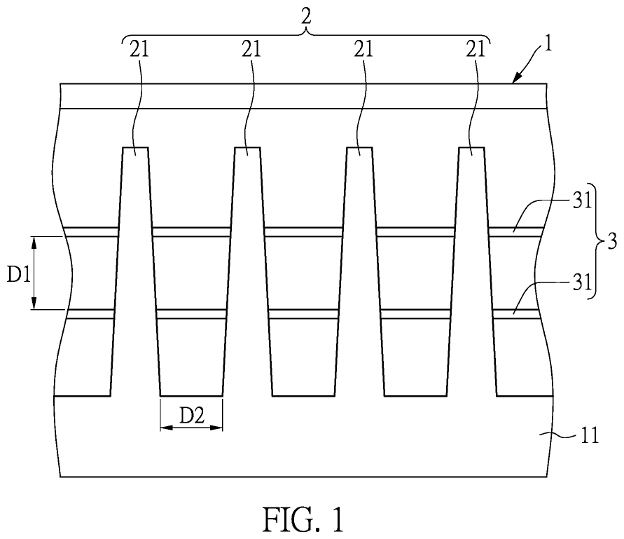

Referring to FIG. 1, a first embodiment of the present disclosure provides a water-cooling device with a composite heat-dissipating structure. As shown in the figure, the water-cooling device with a composite heat-dissipating structure according to the first embodiment includes a casing 1, a main heat-dissipating structure 2 and a layered heat-dissipating structure 3.

As mentioned above, the casing 1 can be used for accommodating a working fluid, such as pure water, ammonia, methanol, acetone, heptane or the like. The shape of the casing 1 can be appropriately changed according to needs, and is not limited thereto. In another embodiment, the casing 1 can be a closed structure or a semi-open structure.

In the present embodiment, the casing 1 includes a heat-dissipating substrate 11, which is integrally formed at a bottom of the casing 1, or is combined to the bottom of the casing 1 by processing (such as soldering) or by contact. Further, the heat-dissipating substrate 11 can be made of a material with a high thermal conductivity, such as aluminum, copper, silver or alloys thereof.

In the present embodiment, the main heat-dissipating structure 2 includes a plurality of heat-dissipating fins 21 arranged vertically and in parallel to each other that are connected to the heat-dissipating substrate 11. That is, the plurality of heat-dissipating fins 21 are perpendicular to the heat-dissipating substrate 11. Further, the plurality of heat-dissipating fins 21 are integrally connected to the heat-dissipating substrate 11, or are processed and combined to the heat-dissipating substrate 11. That is, the plurality of the heat-dissipating fins 21 and the heat-dissipating substrate 11 can be formed integrally or by soldering, so that the plurality of the heat-dissipating fins 21 and the heat-dissipating substrate 11 become an integral structure. Additionally, the heat-dissipating fins 21 can be made of a material with a high thermal conductivity, such as aluminum, copper, silver or alloys thereof.

In the present embodiment, the layered heat-dissipating structure 3 includes a plurality of horizontal heat-dissipating bodies 31 arranged horizontally and in parallel to each other that are connected to the plurality of heat-dissipating fins 21 arranged vertically and in parallel to each other. That is, the plurality of horizontal heat-dissipating bodies 31 are perpendicular to the plurality of heat-dissipating fins 21 and parallel to the heat-dissipating substrate 11.

Moreover, the horizontal heat-dissipating bodies 31 in the present embodiment are each made of a metal plate, and each of the heat-dissipating fins 21 passes through the respective metal plate in sequence. The heat-dissipating fins 21 and the metal plates can form an integral composite heat-dissipating structure by techniques such as soldering or welding. Moreover, the metal plate can be made of a material with a high thermal conductivity, such as aluminum, copper, silver or alloys thereof. Accordingly, in the present embodiment, the plurality of metal plates arranged horizontally and in parallel to each other are connected to the plurality of heat-dissipating fins 21 arranged vertically and in parallel to each other, so as to increase a surface area of an overall structure that is in contact with the working fluid, thereby enhancing a heat dissipation effect.

Furthermore, a distance D1 between the plurality of metal plates arranged horizontally and in parallel to each other can be greater than or equal to a distance D2 between the plurality of heat-dissipating fins 21 arranged vertically and in parallel to each other, which allows the working fluid to pass through more easily, so that a large amount of the working fluid can flow through spaces between the metal plates.

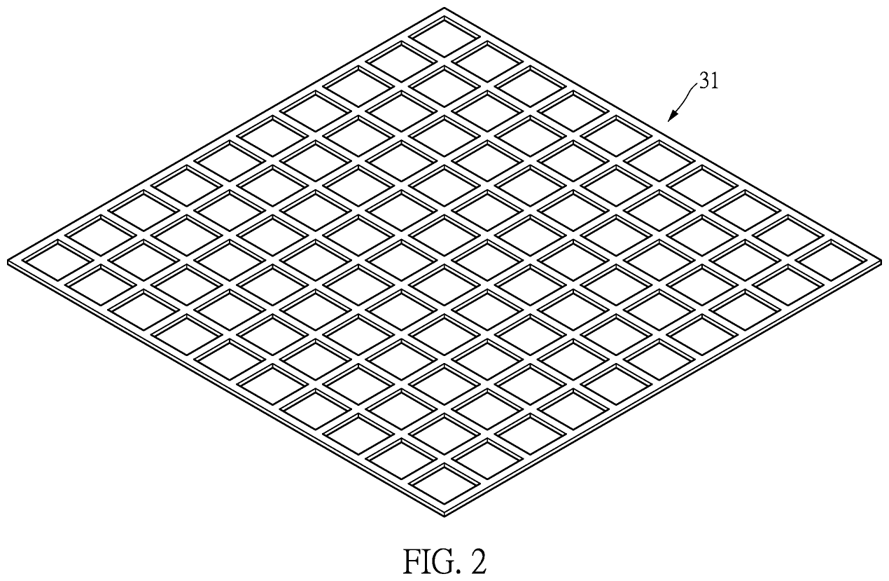

Referring to FIG. 2, the horizontal heat-dissipating bodies as illustrated in FIG. 1 are shown in another configuration. As shown in the figure, the horizontal heat-dissipating bodies 31 are made of a metal mesh with a high thermal conductivity to allow the working fluid to pass through more easily.

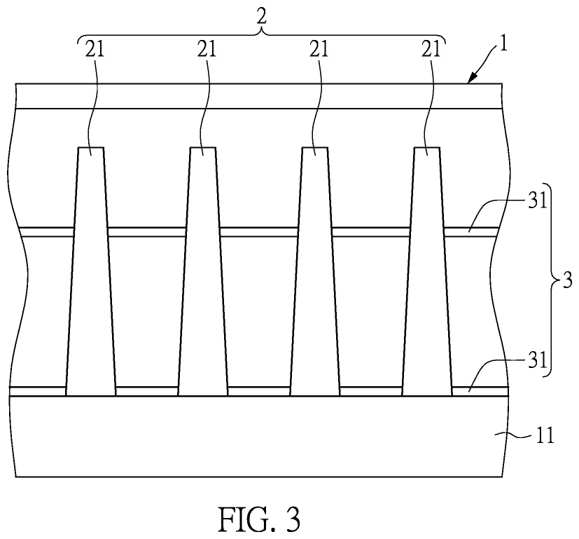

Referring to FIG. 3, a second embodiment of the present disclosure provides a water-cooling device with a composite heat-dissipating structure. As shown in the figure, in the water-cooling device with a composite heat-dissipating structure according to the second embodiment of the present disclosure, the plurality of horizontal heat-dissipating bodies 31 arranged horizontally and in parallel to each other are connected to the plurality of the heat dissipating fins 21 arranged vertically and in parallel to each other, and a lowermost horizontal heat-dissipating body 31 is in contact with or combined to the heat-dissipating substrate 11.

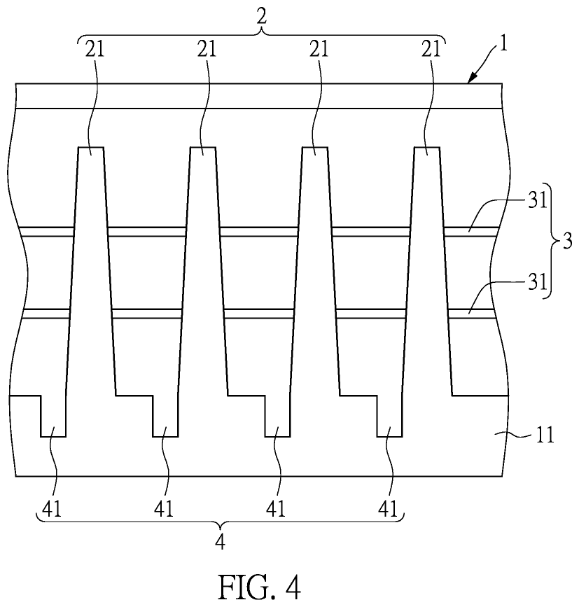

Referring to FIG. 4, a third embodiment of the present disclosure provides a water-cooling device with a composite heat-dissipating structure. As shown in the figure, the water-cooling device with a composite heat-dissipating structure according the third embodiment further includes a heat-dissipating substructure 4.

In the present embodiment, the heat-dissipating substructure 4 includes a plurality of substrate grooves 41 formed on the heat-dissipating substrate 11 to increase the surface area of the overall structure that is in contact with the working fluid to achieve an enhanced heat dissipation effect. Further, the substrate grooves 41 are formed on the heat-dissipating substrate 11 by a nano-scaled pulsed laser processing, and due to a high processing accuracy thereof, the accuracy of the substrate grooves 41 reaches a nano-scaled level.

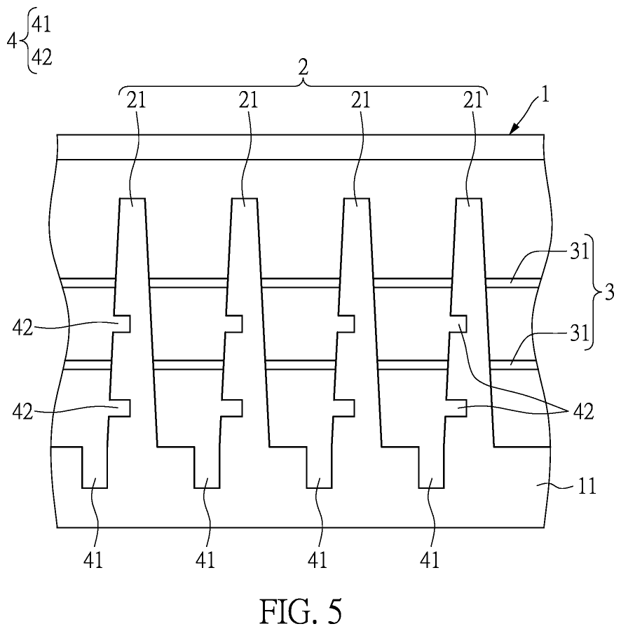

Referring to FIG. 5, a fourth embodiment of the present disclosure provides a water-cooling device with a composite heat-dissipating structure. As shown in the figure, the heat-dissipating substructure 4 of the water-cooling device with a composite heat-dissipating structure according to the fourth embodiment further includes a plurality of fin grooves 42.

In the present embodiment, the heat-dissipating substructure 4 includes the plurality of substrate grooves 41 formed on the heat-dissipating substrate 11 and the plurality of fin grooves 42 formed on the heat-dissipating fins 21 to increase the surface area of the overall structure that is in contact with the working fluid, thereby achieving an enhanced heat dissipation effect. Further, the fin grooves 42 are formed on the heat-dissipating fins 21 by a nano-scaled pulsed laser processing, and due to a high processing accuracy thereof, the accuracy of the substrate grooves 41 reaches a nano-scaled level.

### Beneficial Effects of the Embodiment

In conclusion, in the water-cooling device with a composite heat dissipation structure provided by the present disclosure, through the plurality of horizontal heat-dissipating bodies 31 arranged horizontally and in parallel to each other being connected to the plurality of heat-dissipating fins 21 arranged vertically and in parallel to each other, the surface area of the overall structure that is in contact with the working fluid is increased, so as to achieve an enhanced heat dissipation effect. Moreover, the distance between the horizontal heat-dissipating bodies 31 arranged horizontally and in parallel to each other is greater than or equal to the distance between the heat-dissipating fins 21 arranged vertically and in parallel to each other, which allows the working fluid to pass through more easily, so that a large amount of the working fluid can flow through the spaces between the horizontal heat-dissipating bodies 31.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A water-cooling device with a composite heat-dissipating structure, comprising:
a casing used for accommodating a working fluid, the casing including a heat-dissipating substrate;
a main heat-dissipating structure, including a plurality of heat-dissipating fins arranged vertically and in parallel to each other that are connected to the heat-dissipating substrate; and
a layered heat-dissipating structure, including a plurality of horizontal heat-dissipating bodies arranged horizontally and in parallel to each other that are connected to the plurality of heat-dissipating fins arranged vertically and in parallel to each other, and a distance between the plurality of horizontal heat-dissipating bodies arranged horizontally and in parallel to each other is greater than or equal to a distance between the plurality of heat-dissipating fins arranged vertically and in parallel to each other.

2. The water-cooling device according to claim 1, wherein the horizontal heat-dissipating body is a metal plate with a high thermal conductivity.

3. The water-cooling device according to claim 1, wherein the horizontal heat-dissipating body is a metal mesh with a high thermal conductivity.

4. The water-cooling device according to claim 1, wherein the plurality of heat-dissipating fins and the heat-dissipating substrate are formed integrally or by welding.

5. The water-cooling device according to claim 1, wherein the plurality of heat-dissipating fins and the plurality of horizontal heat-dissipating bodies form an integral composite heat-dissipating structure.

6. The water-cooling device according to claim 1, wherein a lowermost horizontal heat-dissipating body of the plurality of horizontal heat-dissipating bodies is in contact with or combined to the heat-dissipating substrate.

7. The water-cooling device according to claim 1, further comprising a heat-dissipating substructure, wherein the heat-dissipating substructure includes a plurality of substrate grooves formed on the heat-dissipating substrate.

8. The water-cooling device according to claim 7, wherein the substrate grooves are formed on the heat-dissipating substrate by a nano-scaled pulsed laser processing.

9. The water-cooling device according to claim 1, further comprising a heat-dissipating substructure, wherein the heat-dissipating substructure includes a plurality of substrate grooves formed on the heat-dissipating substrate and a plurality of fin grooves formed on the heat-dissipating fins.

10. The water-cooling device according to claim 9, wherein the substrate grooves are formed on the heat-dissipating substrate by a nano-scaled pulsed laser processing, and the fin grooves are formed on the heat-dissipating fins by a nano-scaled pulsed laser processing.
